(19) United States
(12) Patent Application Publication
(10) Pub. No.: US 2006/0186314 A1
(43) Pub. Date: Aug. 24, 2006

(54) Partially transparent mirror having selectively activated light portion

(76) Inventor: Anthony Kit Lun Leung, North Point (CN)

Correspondence Address: STEVEN A. GARNER, ESQ.;CONAIR CORPORATION, ONE CUMMINGS POINT ROAD, STAMFORD, CT, 06902, US

(21) Appl. No.: 11/317,040

(22) Filed: Dec. 22, 2005

Related U.S. Application Data
(60) Provisional application No. 60/640,381, filed on Dec. 30, 2004.

(51) Int. Cl. H01L 27/00

(52) U.S. Cl. 250/208.1

(57) ABSTRACT

A lighted mirror has a glass surface that is provided with a reflective layer beneath the glass, such as a reflective adhesive label, wherein the reflective layer does not cover the entire glass surface. The un-covered glass surface is treated with a thinly deposited layer of aluminum which is semi-transparent. In a non-illuminated state the un-covered glass surface acts as a mirror in the same manner as a conventional “one-way” mirror; while in an illuminated state the un-covered glass surface allows light from a selectively activated light source to pass through.

### CROSS-REFERENCE TO RELATED APPLICATIONS

This application claims priority from U.S. Provisional application 60/640,381, filed Dec. 30, 2004.

### BACKGROUND AND OBJECT OF THE INVENTION

1. Field of the Invention

The present invention relates to mirrors and, more particularly, to lighted mirrors that have a portion that can be selectively lighted.

2. Description of Related Art

It is known in the art to provide mirrors having a selectively activated light source, sometimes of varying power output, for providing light through or adjacent to a surface of the mirror frame in order to provide a user with an ambient light condition that visually simulates a certain type of environment. It is known to have lights of varying power outputs and/or of varying color lenses to simulate a variety of light conditions. Such known mirrors provide one or more light sections surrounding or adjacent to the reflective mirror surface. The light sections can be integral to the frame, or they can be under the same glass or transparent surface of the reflective material. In either situation, the light sections do not provide a reflective surface. Instead, they are dedicated light surfaces that remain whether or not they are activated or illuminated.

It is desirable to provide a mirror in which, when in a non-illuminated mode, maximizes the reflective mirror surface. In addition, it is desirable to provide an illuminated mirror that is inexpensive and less complex to manufacture, and that is more reliable and durable, than known designs. These objectives and others are achieved by the present invention

### BRIEF SUMMARY OF THE INVENTION

The present invention is directed to a novel design for a lighted mirror in which a glass surface is provided with a reflective layer beneath the glass, such as a reflective adhesive label, wherein the reflective layer does not cover the entire glass surface. The un-covered glass surface is treated with a thinly deposited layer of aluminum which is semi-transparent. Thus, in a non-illuminated state the un-covered glass surface acts as a mirror in the same manner as a conventional “one-way” mirror; while in an illuminated state the un-covered glass surface allows light from a selectively activated light source to pass through, thereby casting a desired ambient light condition out onto a user adjacent to the reflective surface.

### BRIEF DESCRIPTION OF THE DRAWINGS

FIG. 1 is a schematic illustration of a front view of a mirror according to the present invention shown in a non-illuminated condition.

FIG. 2 is a schematic illustration of a front view of a mirror according to the present invention shown in a first illuminated condition.

FIG. 3 is a schematic illustration of a front view of a mirror according to the present invention shown in a second illuminated condition.

FIG. 4a is a schematic, exploded, partial view of glass plate and reflective label components according to the present invention.

FIG. 4b is a schematic, side view of glass plate and reflective label components according to the present invention.

FIG. 5 is a schematic, exploded, side view of a heat source and aluminum source being utilized to deposit an aluminum layer to a glass plate component according to the present invention.

### DETAILED DESCRIPTION OF THE PREFERRED EMBODIMENT

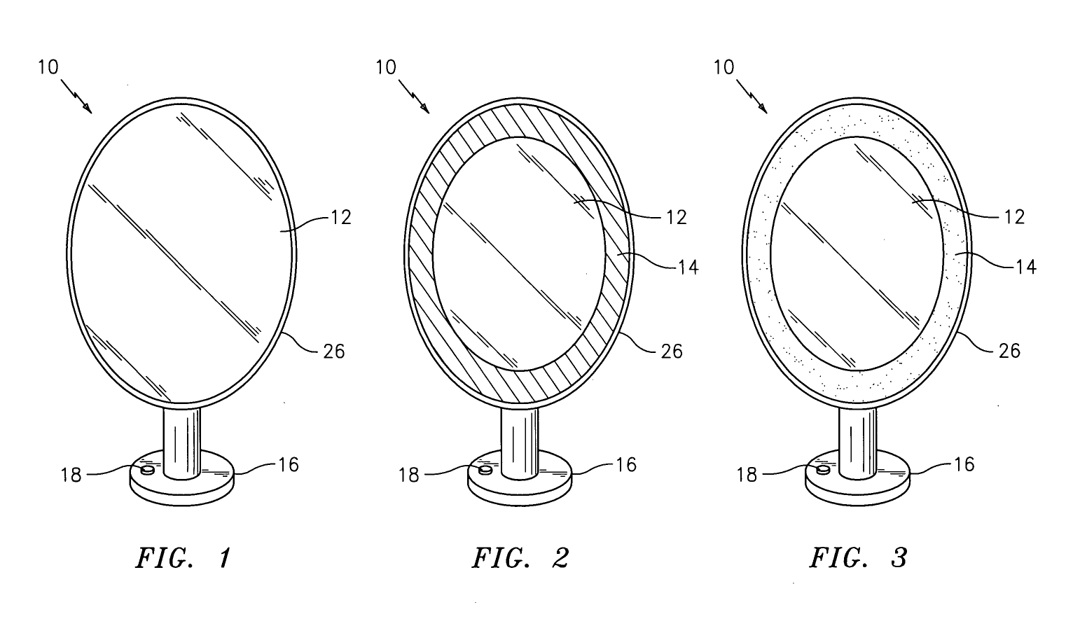

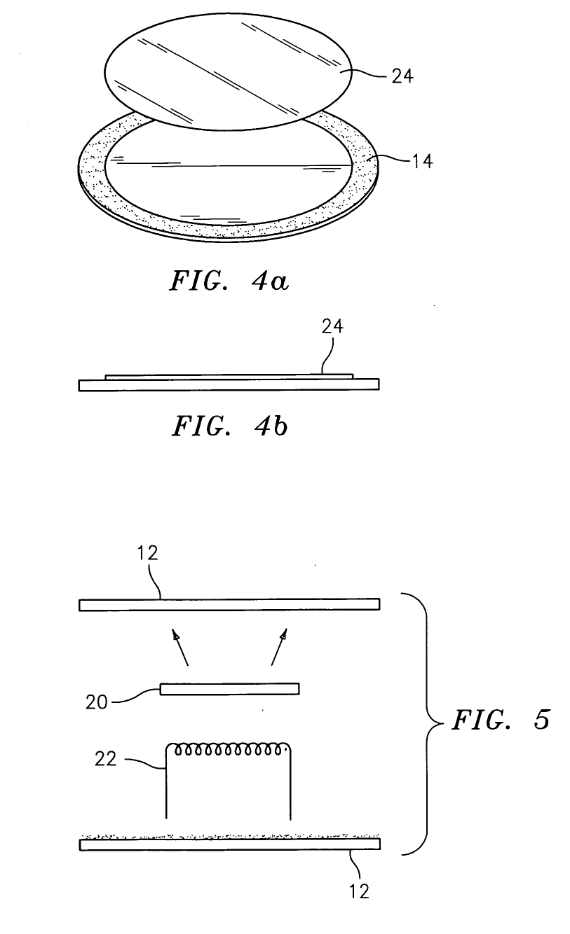

A mirror (10) according to the present invention is shown in FIGS. 1-3. A glass surface (12) is suspended in a frame (26) that can be of any shape such as an oval as shown. The frame (16) is supported by a pedestal or base (16). As shown in FIG. 1, in a non-illuminated state the entire surface area of the glass surface (12) is reflective and forms a mirror, as represented by the shading in FIG. 1. Upon activation of a switch (18), a conventional electrically-powered light source, such as a light bulb (not shown), which is housed behind the glass surface (12), illuminates a lighted section (14) of the glass surface (12). The lighted section (14) is shown in different shades of illumination in FIG. 2 and FIG. 3 to illustrate that, with varying power to the light source or with varying output of the light source, the amount of light passing through the lighted section (14) of glass (12) can be selectively varied. In the illuminated state shown in FIG. 2 and FIG. 3, no light passes through the glass except for through the lighted section (14). The un-lighted section of the glass (12) (i.e., the section other than that represented with the numeral 14), has a material or medium that does not allow light penetration. In the preferred embodiment, the un-lighted section is defined by an adhesive label (24) that is adhered to the glass surface (12), as shown in FIGS. 4a-4b. The label (24) has a reflective surface on the side that contacts the glass (12), so that it performs as a mirror when viewed in the views shown in FIGS. 1-3. Various known means of adhering a reflective background behind the glass surface (12) may be used instead of using an adhesive label (24).

Referring to FIG. 5, the lighted section (14) is formed by depositing a light layer of aluminum onto the glass (12), in a layer of appropriate density and thickness to be semi-transparent in order to allow the light source behind the mirror to penetrate when activated, but to otherwise appear as a reflective mirror when the light source is not activated. Deposition can be done in any one of a variety of known means, but in the preferred embodiment it is achieved by applying heat from a heat source (22) to an aluminum bar (20) in a manner to cause controlled deposition onto the glass surface (12). By applying the label (24) first, the portion of the glass (12) that is not covered by the label (24) will receive the aluminum deposition and result in the semi-transparent portion (14).

While a preferred embodiment of the invention has been herein disclosed and described, it is understood that various modifications can be made without departing from the scope of the invention.

What is claimed is:

1) A mirror comprising
a transparent surface having a first side and a second side;
a reflective layer adjacent to said first side and covering a first portion of said transparent surface, whereby a second portion of said transparent surface is not covered by said reflective layer;
a semi-transparent layer adjacent to said first side and covering said second portion of said transparent surface; and
a light source adjacent to said transparent surface that is adapted to be selectively activated or de-activated.

2) A mirror according to claim 1, wherein
light emitted from said light source penetrates said second portion, but is prevented from penetrating said first portion.

3) A mirror according to claim 1, wherein
said reflective layer comprises an adhesive-backed film adapted to adhere to said transparent surface.

4) A mirror according to claim 1, wherein
said transparent surface is a glass surface.

5) A mirror according to claim 3, wherein
said semi-transparent layer is a deposited layer of aluminum.

6) A mirror according to claim 1, wherein
said light source comprises a light bulb.

7) A mirror according to claim 1, wherein
said light source is selectively variable in its intensity of light emission.
